(19) United States
(12) Patent Application Publication
(10) Pub. No.: US 2024/0172504 A1
(43) Pub. Date: May 23, 2024

(54) DISPLAY APPARATUS

(71) Applicant: Samsung Display Co., Ltd., Yongin-si (KR)

(72) Inventors: Kwangchul Jung, Yongin-si (KR); Yongjun Jo, Yongin-si (KR); Sungmin Son, Yongin-si (KR); Jaejin Song, Yongin-si (KR)

(73) Assignee: Samsung Display Co., Ltd., Yongin-si (KR)

(21) Appl. No.: 18/461,015

(22) Filed: Sep. 5, 2023

(30) Foreign Application Priority Data
Nov. 22, 2022 (KR) 10-2022-0157502

(51) Int. Cl. H10K 59/131; H10K 59/121

(52) U.S. Cl. CPC H10K 59/131; H10K 59/1213; H10K 59/1216

(57) ABSTRACT

A display apparatus includes a substrate, a scan line disposed over the substrate and extending in a first direction, an initialization voltage line disposed over the substrate and extending in the first direction, a first thin-film transistor including a first semiconductor layer and a first gate electrode insulated from the first semiconductor layer, the first semiconductor layer including a silicon semiconductor, and a second thin-film transistor including a second semiconductor layer and a second gate electrode insulated from the second semiconductor layer, the second semiconductor layer including an oxide semiconductor, wherein the second semiconductor layer is disposed between the scan line and the initialization voltage line in a plan view, and the second gate electrode extends from the scan line in a second direction perpendicular to the first direction.

### CROSS-REFERENCE TO RELATED APPLICATION(S)

This application claims priority to and benefits of Korean Patent Application No. 10-2022-0157502 under 35 U.S.C. § 119, filed on Nov. 22, 2022, in the Korean Intellectual Property Office, the entire contents of which are incorporated herein by reference.

### BACKGROUND

### 1. Technical Field

One or more embodiments relate to a display apparatus.

### 2. Description of the Related Art

As a display technology of visually expressing various electrical signals is researched, various display apparatuses having excellent characteristics such as being lightweight, low power consumption, and the like have been developed.

Display apparatuses may include liquid crystal display apparatuses that use light from a backlight without spontaneously emitting light, or light-emitting display apparatuses including light-emitting elements that emit light. The light-emitting display apparatus may include light-emitting elements each including an emission layer.

### SUMMARY

One or more embodiments provide a display apparatus with high resolution capable of improving display quality and reducing power consumption.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a display apparatus may include a substrate, a scan line disposed over the substrate and extending in a first direction, an initialization voltage line disposed over the substrate and extending in the first direction, a first thin-film transistor including a first semiconductor layer and a first gate electrode insulated from the first semiconductor layer, the first semiconductor layer including a silicon semiconductor, and a second thin-film transistor including a second semiconductor layer and a second gate electrode insulated from the second semiconductor layer, the second semiconductor layer including an oxide semiconductor, wherein the second semiconductor layer may be disposed between the scan line and the initialization voltage line in a plan view, and the second gate electrode may extend from the scan line in a second direction perpendicular to the first direction.

The second semiconductor layer may be electrically connected to the initialization voltage line.

A vertical distance from the substrate to the second semiconductor layer may be greater than a vertical distance from the substrate to the first semiconductor layer.

The second thin-film transistor may further include a third gate electrode disposed below the second semiconductor layer to overlap the second semiconductor layer, and the third gate electrode may extend from the initialization voltage line in the second direction.

The display apparatus may further include a first capacitor including a lower electrode and an upper electrode over the lower electrode, wherein the lower electrode and the first gate electrode may be disposed on a same layer, and the upper electrode and the third gate electrode may be disposed on a same layer.

The display apparatus may further include an emission control line spaced apart from the initialization voltage line and extending in the first direction, wherein the emission control line may overlap the scan line.

The emission control line and the first gate electrode may be disposed on a same layer.

The display apparatus may further include a third thin-film transistor including a third semiconductor layer and a fourth gate electrode insulated from the third semiconductor layer, wherein the third semiconductor layer may include an oxide semiconductor, and the third semiconductor layer may be spaced apart from the second semiconductor layer of the second thin-film transistor.

The display apparatus may further include a second capacitor including a lower electrode and an upper electrode, wherein the lower electrode and the first gate electrode may be disposed on a same layer, and the upper electrode and the third semiconductor layer may be disposed on a same layer.

The upper electrode of the second capacitor may extend from the third semiconductor layer.

According to one or more embodiments, a display apparatus may include a substrate, a scan line disposed over the substrate and extending in a first direction, an initialization voltage line disposed over the substrate and extending in the first direction, a first thin-film transistor disposed over the substrate and including a first semiconductor layer and a first gate electrode insulated from the first semiconductor layer, the first semiconductor layer including a silicon semiconductor, and a second thin-film transistor including a second semiconductor layer, a second gate electrode, and a third gate electrode, the second semiconductor layer including an oxide semiconductor, the second gate electrode may be disposed over the second semiconductor layer, and the third gate electrode may overlap the second gate electrode and may be disposed below the second semiconductor layer, wherein the third gate electrode may extend from the initialization voltage line in a second direction perpendicular to the first direction.

The second semiconductor layer may be disposed between the scan line and the initialization voltage line in a plan view.

The second semiconductor layer may be electrically connected to the initialization voltage line.

The second gate electrode may extend from the scan line in the second direction.

The display apparatus may further include a first capacitor including a lower electrode and an upper electrode over the lower electrode, wherein the lower electrode and the first gate electrode may be disposed on a same layer, and the upper electrode and the third gate electrode may be disposed on a same layer.

The display apparatus may further include an emission control line spaced apart from the initialization voltage line and extending in the first direction, wherein the emission control line may overlap the scan line.

The emission control line and the first gate electrode may be disposed on a same layer.

The display apparatus may further include a third thin-film transistor including a third semiconductor layer and a fourth gate electrode insulated from the third semiconductor layer, wherein the third semiconductor layer may include an oxide semiconductor, and the third semiconductor layer may be spaced apart from the second semiconductor layer of the second thin-film transistor.

The display apparatus may further include a second capacitor including a lower electrode and an upper electrode, wherein the lower electrode and the first gate electrode may be disposed on a same layer, and the upper electrode and the third semiconductor layer may be disposed on a same layer.

The upper electrode of the second capacitor may extend from the third semiconductor layer.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic plan view of a display apparatus according to an embodiment;

FIG. 2 is a schematic diagram of an equivalent circuit of a light-emitting diode of a display apparatus and a sub-pixel circuit electrically connected thereto, according to an embodiment;

FIG. 3 is a schematic plan view of a display apparatus according to an embodiment;

FIG. 4 is a schematic cross-sectional view of the display apparatus, taken along line A-A′ of FIG. 3;

FIG. 5 is a schematic plan view of positions of elements arranged in a sub-pixel circuit of a display apparatus according to an embodiment;

FIGS. 6A, 6B, 6C, 6D, 6E, 6F, 6G, and 6H are schematic plan views showing a process of forming elements arranged in a sub-pixel circuit of a display apparatus, according to an embodiment;

FIG. 7 is an enlarged schematic plan view of a region X of FIG. 5; and

FIG. 8 is a schematic cross-sectional view of a portion of the display apparatus, taken along line B-B′ of FIG. 7.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments are described in detail with reference to the accompanying drawings. In case that description is made with reference to the drawings, like reference numerals are used for like or corresponding elements.

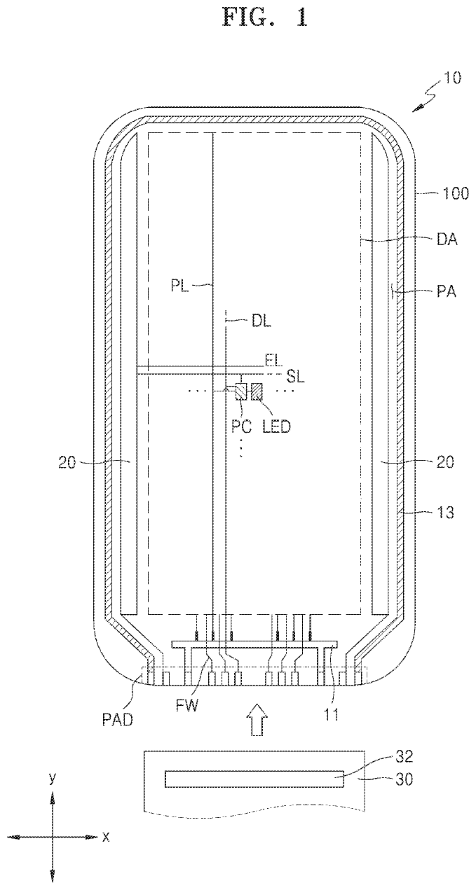

FIG. 1 is a schematic plan view of a display apparatus 10 according to an embodiment.

Referring to FIG. 1, various elements of the display apparatus 10 may be disposed on a substrate 100. The substrate 100 may include a display area DA and a peripheral area PA surrounding the display area DA. The display area DA may be protected from external air, moisture, or the like by an encapsulation member which covers the display area DA.

Light-emitting diodes LED may be arranged in the display area DA of the substrate 100. The display apparatus 10 may display images by using light emitted from the light-emitting diodes LED. Each light-emitting diode LED may emit, for example, red, green, or blue light.

In an embodiment, the light-emitting diode LED may include an organic light-emitting diode including an organic material as a light-emission material. In another embodiment, the light-emitting diode LED may be an inorganic light-emitting diode including an inorganic material. The inorganic light-emitting diode may include a PN-junction diode including inorganic material semiconductor-based materials. In case that a forward voltage is applied to a PN-junction diode, holes and electrons are injected and energy created by recombination of the holes and the electrons is converted to light energy, and thus, light of a preset (or certain) color may be emitted.

The size of the light-emitting diode LED may be microscales or nanoscales. In an example, the light-emitting diode LED may be a micro light-emitting diode. In another example, the light-emitting diode LED may be a nanorod light-emitting diode. The nanorod light-emitting diode may include gallium nitride (GaN).

In an embodiment, the light-emitting diode LED may be a quantum-dot light-emitting diode. As described above, an emission layer of the light-emitting diode LED may include an organic material, an inorganic material, quantum dots, an organic material and quantum dots, or inorganic material and quantum dots. Hereinafter, for convenience of description, the case where the light-emitting diode LED includes an organic light-emitting diode is described.

Each light-emitting diode LED may be electrically connected to a sub-pixel circuit PC, and each sub-pixel circuit PC may include transistors and a capacitor. The sub-pixel circuits PC may each be electrically connected to peripheral circuits arranged in the peripheral area PA. Peripheral circuits arranged in the peripheral area PA may include a scan driving circuit 20, a terminal part PAD, a driving voltage supply line 11, and common voltage supply lines 13.

The scan driving circuit 20 may provide scan signals to each of the sub-pixel circuits PC through the scan line SL and may provide emission control signals to each of the sub-pixel circuits PC through an emission control line EL. The scan driving circuits 20 may be arranged on two opposite sides around the display area DA. The sub-pixel circuit PC arranged in the display area DA may be electrically connected to at least one of the scan driving circuits 20 provided to the left side or the right side of the display apparatus 10.

The terminal part PAD may be arranged on a side of the substrate 100. The terminal part PAD may be exposed and connected (e.g., electrically connected) to a display circuit board 30 by not being covered by an insulating layer. A display driver 32 may be arranged on the display circuit board 30.

The display driver 32 may generate control signals transferred to the scan driving circuit 20. The display driver 32 may generate a data signal, and the generated data signal may be transferred to the sub-pixel circuit PC through a fan-out wiring FW and a data line DL connected (e.g., electrically connected) to the fan-out wiring FW.

The display driver 32 may supply a driving voltage ELVDD to the driving voltage supply line 11 and may supply a common voltage ELVSS to the common voltage supply line 13. The driving voltage ELVDD may be applied to the sub-pixel circuit PC through a driving voltage line PL connected (e.g., electrically connected) to the driving voltage supply line 11, and the common voltage ELVSS may be applied to an opposite electrode (e.g., a cathode) of the light-emitting diode LED through the common voltage supply line 13.

The driving voltage supply line 11 may extend in an x-axis direction below the display area DA. The common voltage supply line 13 may have a loop shape having one open side to partially surround the display area DA.

The display apparatus 10 of FIG. 1 may be an apparatus for displaying moving images or still images and may include portable electronic apparatuses such as mobile phones, smartphones, tablet personal computers, mobile communication terminals, electronic organizers, electronic books, portable multimedia players (PMPs), navigations, and ultra mobile personal computers (UMPCs), and the like. In another example, the display apparatus 10 may be implemented as a display screen of various products including televisions, notebook computers, monitors, advertisement boards, Internet of things (IoT), and the like. For example, the display apparatus 10 according to an embodiment may be applied to wearable devices including smartwatches, watchphones, glasses-type displays, and head-mounted displays (HMDs). For example, the display apparatus 10 according to an embodiment may be implemented as instrument panels for automobiles, center fascias for automobiles, or center information displays (CID) arranged on a dashboard, room mirror displays that replace side mirrors of automobiles, and displays arranged on the backside of front seats as an entertainment for back seats of automobiles.

In an embodiment, the display apparatus 10 may be a foldable display apparatus. In an example, the display apparatus 10 may be folded around a folding axis extending in a first direction (e.g., the x-axis direction) or a second direction (e.g., a y-axis direction).

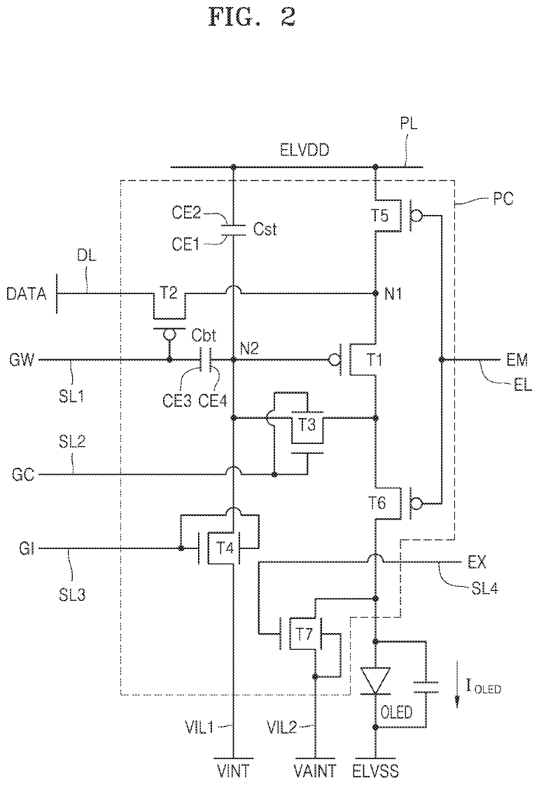

FIG. 2 is a schematic diagram of an equivalent circuit of one of light-emitting diodes of a display apparatus and a sub-pixel circuit connected thereto, according to an embodiment.

Referring to FIG. 2, the light-emitting diode may be electrically connected to the sub-pixel circuit PC. The sub-pixel circuit PC may include transistors and a capacitor. In an embodiment, the light-emitting diode may be an organic light-emitting diode OLED.

In an example, the sub-pixel circuit PC may include thin-film transistors T1, T2, T3, T4, T5, T6, and T7, a first capacitor Cst, and a second capacitor Cbt. In an embodiment, the thin-film transistors T1, T2, T3, T4, T5, T6, and T7 may include a driving transistor (e.g., first thin-film transistor) T1, a switching transistor T2, a compensation transistor (e.g., third thin-film transistor) T3, a first initialization transistor T4, an operation control transistor T5, an emission control transistor T6, and a second initialization transistor (e.g., second thin-film transistor) T7. However, embodiments are not limited thereto.

The organic light-emitting diode OLED may include a sub-pixel electrode and an opposite electrode. The sub-pixel electrode of the organic light-emitting diode OLED may be connected to the driving transistor T1 through the emission control transistor T6 and may receive a driving current I_{OLED}, and the opposite electrode may receive the common voltage ELVSS. The organic light-emitting diode OLED may generate light of brightness corresponding to the driving current I_{OLED}.

In an embodiment, some of the thin-film transistors T1, T2, T3, T4, T5, T6, and T7 may be n-channel metal-oxide semiconductor field-effect transistors (n-channel MOSFETs; NMOS), and the remaining transistors may be p-channel metal-oxide semiconductor field-effect transistors (p-channel MOSFETs; PMOS). In an example, as shown in FIG. 2, among the thin-film transistors T1, T2, T3, T4, T5, T6, and T7, the compensation transistor T3, the first initialization transistor T4, and the second initialization transistor T7 may be NMOS, and the remaining transistor may be PMOS.

The signal lines may include a first scan line SL1, a second scan line SL2, a third scan line SL3, an emission control line EL, a fourth scan line SL4, and the data line DL. The first scan line SL1 may transfer a first scan signal GW, the second scan line SL2 may transfer a second scan signal SC, the third scan line SL3 may transfer a third scan signal GI to the first initialization transistor T4, the emission control line EL may transfer an emission control signal EM to the operation control transistor T5 and the emission control transistor T6, the fourth scan line SL4 may transfer a fourth scan signal EX to the second initialization transistor T7, and the data line DL may transfer a data signal DATA.

The driving voltage line PL may transfer the driving voltage ELVDD to the driving transistor T1. A first initialization voltage line VIL1 may transfer a first initialization voltage VINT to the sub-pixel circuit PC. The first initialization voltage VINT may initialize the driving transistor T1. A second initialization voltage line VIL2 may transfer a second initialization voltage VAINT to the sub-pixel circuit PC. The second initialization voltage VAINT may initialize the organic light-emitting diode OLED. For example, the first initialization voltage line VIL1 may transfer the first initialization voltage VINT to the first initialization transistor T4, and the second initialization voltage line VIL2 may transfer the second initialization voltage VAINT to the second initialization transistor T7.

A gate electrode of the driving transistor T1 may be connected (e.g., electrically connected) to the first capacitor Cst and the second capacitor Cbt, one of a source region and a drain region of the driving transistor T1 may be connected (e.g., electrically connected) to the driving voltage line PL through the operation control transistor T5 and a first node N1, and the other of the source region and the drain region of the driving transistor T1 may be electrically connected to the sub-pixel electrode of the organic light-emitting diode OLED through the emission control transistor T6. The driving transistor T1 may receive a data signal DATA and supply the driving current I_{OLED} to the organic light-emitting diode OLED according to a switching operation of the switching transistor T2.

A gate electrode of the switching transistor T2 may be connected (e.g., electrically connected) to the first scan line SL1 that transfers a first scan signal SW and the second capacitor Cbt, one of a source region and a drain region of the switching transistor T2 may be connected (e.g., electrically connected) to the data line DL, and the other of the source region and the drain region of the switching transistor T2 may be connected (e.g., electrically connected) to the driving transistor T1 through the first node N1 and connected (e.g., electrically connected) to the driving voltage line PL through the operation control transistor T5. The switching transistor T2 may be turned on according to a first scan signal GW transferred through the first scan line SL1 and may perform a switching operation for transferring a data signal DATA received via the data line DL to the driving transistor T1 through the first node N1.

A gate electrode of the compensation transistor T3 may be connected (e.g., electrically connected) to the first scan line SL1. One of a source region and a drain region of the compensation transistor T3 may be connected (e.g., electrically connected) to the sub-pixel electrode of the organic light-emitting diode OLED through the emission control transistor T6. The other of the source region and the drain region of the compensation transistor T3 may be connected (e.g., electrically connected) to the first capacitor Cst and the gate electrode of the driving transistor T1. The compensation transistor T3 may be turned on according to a first scan signal GW to compensate for a threshold voltage of the driving transistor T1 by diode-connecting the driving transistor T1. The first scan signal GW may be transferred through the first scan line SL1.

A gate electrode of the first initialization transistor T4 may be connected (e.g., electrically connected) to the third scan line SL3. One of a source region and a drain region of the first initialization transistor T4 may be connected (e.g., electrically connected) to the first initialization voltage line VIL1. The other of the source region and the drain region of the first initialization transistor T4 may be connected (e.g., electrically connected) to a first capacitor electrode CE1 of the first capacitor Cst, and the gate electrode of the driving transistor T1. The first initialization transistor T4 may be turned on according to a third scan signal GI received through the third scan line SL3 and may initialize the voltage of the gate voltage of the driving transistor T1 by transferring the first initialization voltage VINT to the gate electrode of the driving transistor T1.

A gate electrode of the operation control transistor T5 may be connected (e.g., electrically connected) to the emission control line EL, one of a source region and a drain region of the operation control transistor T5 may be connected (e.g., electrically connected) to the driving voltage line PL, and the other of the source region and the drain region of the operation control transistor T5 may be connected (e.g., electrically connected) to the driving transistor T1 and the switching transistor T2 through the first node N1.

A gate electrode of the emission control transistor T6 may be connected (e.g., electrically connected) to the emission control line EL, one of a source region and a drain region of the emission control transistor T6 may be connected (e.g., electrically connected) to the driving transistor T1 and the compensation transistor T3, and the other of the source region and the drain region of the emission control transistor T6 may be electrically connected to the sub-pixel electrode of the organic light-emitting diode OLED.

The operation control transistor T5 and the emission control transistor T6 may be connected (e.g., electrically connected) to an emission control line EL, may simultaneously turned on according to an emission control signal EM transferred through the emission control line EL, and may form a current path such that the driving current I_{OLED} may flow in a direction from the driving voltage line PL to the organic light-emitting diode OLED.

A gate electrode of the second initialization transistor T7 may be connected (e.g., electrically connected) to the fourth scan line SL4, one of a source region and a drain region of the second initialization transistor T7 may be connected (e.g., electrically connected) to the sub-pixel electrode of the organic light-emitting diode OLED, and the other of the source region and the drain region of the second initialization transistor T7 may be electrically connected to the second initialization voltage line VIL2 to receive the second initialization voltage VAINT. The second initialization transistor T7 may be turned on according to a fourth scan signal EX transferred through the fourth scan line SL4 and may initialize the sub-pixel electrode of the organic light-emitting diode OLED.

The first capacitor Cst may include the first capacitor electrode CE1 and a second capacitor electrode CE2. The first capacitor electrode CE1 may be connected to the gate electrode of the driving transistor T1, and the second capacitor electrode CE2 may be connected to the driving voltage line PL. The first capacitor Cst may maintain a voltage applied to the gate electrode of the driving transistor T1 by storing and maintaining a voltage corresponding to a difference between voltages of two opposite end portions of the gate electrode of the driving transistor T1 and the driving voltage line PL.

The second capacitor Cbt may include a third capacitor electrode CE3 and a fourth capacitor electrode CE4. The third capacitor electrode CE3 may be connected (e.g., electrically connected) to the first scan line SL1 and the gate electrode of the switching transistor T2. The fourth capacitor electrode CE4 may be connected (e.g., electrically connected) to the gate electrode of the driving transistor T1 and the first capacitor electrode CE1 of the first capacitor Cst. The second capacitor Cbt may function as a boosting capacitor. In case that a first scan signal GW of the first scan line SL1 is a voltage that turns off the switching transistor T2, the second capacitor Cbt may clearly express a black grayscale by increasing the voltage of a second node N2.

Specific operations of the sub-pixel circuit PC and the organic light-emitting diode OLED according to an embodiment are described below.

In case that a third scan signal GI is supplied through the third scan line SL3 during a first initialization period, the first initialization transistor T4 may be turned on according to the third scan signal GI, and the driving transistor T1 may be initialized by the first initialization voltage VINT supplied from the first initialization voltage line VIL1.

In case that a first scan signal GW and a second scan signal GC are respectively supplied through the first scan line SL1 and the second scan line SL2 during a data programming period. the switching transistor T2 and the compensation transistor T3 may be turned on according to the first scan signal GW and the second scan signal GC. For example, the driving transistor T1 may be diode-connected and forward-biased by the compensation transistor T3 that is turned on. For example, a compensation voltage DATA+Vth may be applied to the gate electrode of the driving transistor T1, where Vth is a negative value. The compensation voltage DATA+Vth may be a voltage reduced by a threshold voltage Vth of the driving transistor T1 from a data signal DATA supplied from the data line DL. The driving voltage ELVDD and the compensation voltage DATA+Vth may be respectively applied to two opposite end portions of the first capacitor Cst, and charge corresponding to a difference between voltages of the two opposite ends may be stored in the first capacitor Cst.

During an emission period, the operation control transistor T5 and the emission control transistor T6 may be turned on according to an emission control signal EM supplied from the emission control line EL. The driving current I_{OLED} corresponding to a voltage difference between the voltage of the gate electrode of the driving transistor T1 and the driving voltage ELVDD occurs, and the driving current I_{OLED} may be supplied to the organic light-emitting diode OLED through the emission control transistor T6.

In case that a fourth scan signal EX is supplied through the fourth scan line SL4 during a second initialization period, the second initialization transistor T7 may be turned on according to the fourth scan signal EX, and the organic light-emitting diode OLED may be initialized by the second initialization voltage VAINT supplied from the second initialization voltage line VIL2.

In an embodiment, at least one of the thin-film transistors T1, T2, T3, T4, T5, T6, and T7 may include a semiconductor layer including oxide, and the remaining transistors may include a semiconductor layer including amorphous silicon or polycrystalline silicon.

For example, the driving transistor T1, which controls the brightness of the display apparatus 10, may include a semiconductor layer including polycrystalline silicon having high reliability, and thus, a high-resolution display apparatus 10 may be implemented through this configuration.

Because the oxide semiconductor has a high carrier mobility and a low leakage current, a voltage drop may not be large even though a driving time is long. For example, because a color change of an image according to a voltage drop is not large even in case that the display apparatus 10 is driven at low frequencies, the display apparatus 10 may be driven at low frequencies.

Because the oxide semiconductor has an advantage of a low leakage current, at least one of the compensation transistor T3, the first initialization transistor T4, and the second initialization transistor T7 connected (e.g., electrically connected) to the gate electrode of the driving transistor T1 may include an oxide semiconductor, and thus, a leakage current that may flow to the gate electrode of the driving transistor T1 may be prevented, and simultaneously, power consumption may be reduced.

In an embodiment, as shown in FIG. 2, all of the compensation transistor T3, the first initialization transistor T4, and the second initialization transistor T7 may include an oxide semiconductor, and thus, power consumption of the display apparatus 10 may be reduced.

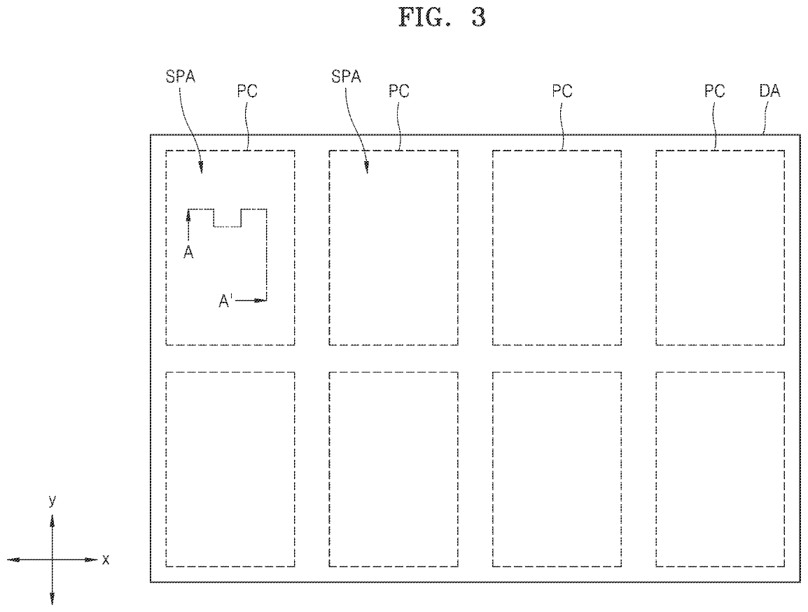

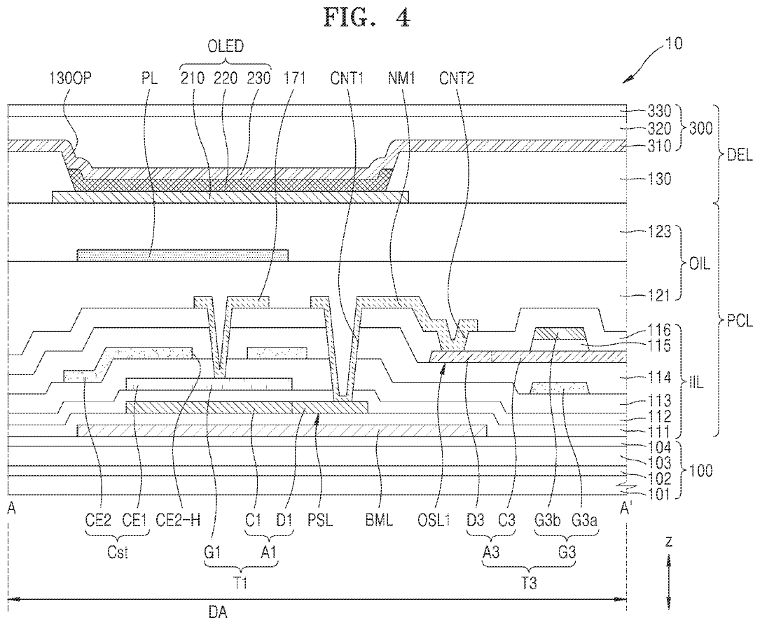

FIG. 3 is a schematic plan view of the display apparatus 10 according to an embodiment. FIG. 4 is a schematic cross-sectional view of the display apparatus 10, taken along line A-A′ of FIG. 3.

Referring to FIG. 3, the display area DA may include sub-pixel circuit areas SPA in which the sub-pixel circuits PC are arranged. The sub-pixel circuit areas SPA may be arranged in the first direction (e.g., the x-axis direction) and the second direction (e.g., the y-axis direction). The sub-pixel circuits PC may be arranged in the first direction (e.g., the x-axis direction) and the second direction (e.g., the y-axis direction).

Referring to FIG. 4, in the sub-pixel circuit area SPA included in the display area DA, the display apparatus 10 may include the substrate 100, a sub-pixel circuit layer PCL, and a light-emitting diode layer DEL.

The sub-pixel circuit layer PCL may define the sub-pixel circuit. The sub-pixel circuit layer PCL may include elements of thin-film transistors and the capacitors, and insulating layers disposed under and/or on the elements. FIG. 4 shows the driving transistor T1, the compensation transistor T3, and the first capacitor Cst among the thin-film transistors and the capacitors included in the sub-pixel circuit. For example, the sub-pixel circuit layer PCL may include inorganic insulating layers IIL and organic insulating layers OIL. In an example, as shown in FIG. 4, the inorganic insulating layers IIL may include a first gate insulating layer 112, a first interlayer insulating layer 113, a second interlayer insulating layer 114, a second gate insulating layer 115, and a third interlayer insulating layer 116. The organic insulating layer OIL may include a first organic insulating layer 121 and a second organic insulating layer 123.

The substrate 100 may include a glass material, a ceramic material, metal, plastic, or a flexible or bendable material. In the case where the substrate 100 is flexible or bendable, the substrate 100 may include a polymer resin including polyethersulphone (PES), polyacrylate, polyetherimide (PEI), polyethylene naphthalate (PEN), polyethylene terephthalate (PET), polyphenylene sulfide (PPS), polyarylate, polyimide (PI), polycarbonate (PC), and cellulose acetate propionate (CAP).

The substrate 100 may have a single-layered structure or a multi-layered structure of the above materials and may further include an inorganic layer in the case of the multi-layered structure. In an example, the substrate 100 may include a first organic base layer 101, a first inorganic barrier layer 102, a second organic base layer 103, and a second inorganic barrier layer 104. The first organic base layer 101 and the second organic base layer 103 may each include a polymer resin. The first inorganic barrier layer 102 and the second inorganic barrier layer 104 may function as barrier layers preventing the penetration (or permeation) of external foreign materials, and may include a single layer or a multi-layer including an inorganic insulating material such as silicon nitride and/or silicon oxide.

A bottom metal layer BML may be disposed on the substrate 100. The bottom metal layer BML may include at least one material among aluminum (Al), platinum (Pt), palladium (Pd), silver (Ag), magnesium (Mg), gold (Au), nickel (Ni), neodymium (Nd), iridium (Ir), chromium (Cr), lithium(Li), calcium (Ca), molybdenum (Mo), titanium (Ti), tungsten (W), and copper (Cu). In an embodiment, the bottom metal layer BML may have a molybdenum-single layer, a double-layered structure in which a molybdenum layer and a titanium layer are stacked, or a triple-layered structure in which a titanium layer, an aluminum layer, and a titanium layer are stacked.

A buffer layer 111 may be disposed on the bottom metal layer BML. The buffer layer 111 may include an inorganic insulating layer including an inorganic insulating material such as silicon nitride and/or silicon oxide, and may include a single layer or a multi-layered structure including the above material.

Silicon semiconductor layers of silicon-based transistors may be disposed on the buffer layer 111. FIG. 4 shows a first semiconductor layer A1 of the driving transistor T1 corresponding to a portion of a silicon semiconductor pattern layer PSL. The first semiconductor layer A1 may include a first channel region C1 and impurity regions arranged on two opposite sides of the first channel region C1 and doped with impurities. FIG. 4 shows a second region D1, which is one of the impurity regions arranged on a side of the first channel region C1.

The first gate insulating layer 112 may be disposed on the silicon semiconductor pattern layer PSL. The first gate insulating layer 112 may include an inorganic insulating layer including an inorganic insulating material such as silicon oxide, silicon nitride and/or silicon oxynitride, and may include a single layer or a multi-layered structure including the above material.

A first gate electrode G1 and the first capacitor electrode CE1 may be disposed on the first gate insulating layer 112. Referring to FIG. 4, the first gate electrode G1 and the first capacitor electrode CE1 may be integral with each other. For example, the first gate electrode G1 may perform a function of the first capacitor electrode CE1, or the first capacitor electrode CE1 may perform a function of the first gate electrode G1.

The first gate electrode G1 and/or the first capacitor electrode CE1 may include aluminum (Al), platinum (Pt), palladium (Pd), silver (Ag), magnesium (Mg), gold (Au), Nickel (Ni), neodymium (Nd), iridium (Ir), chrome (Cr), lithium (Li), calcium (Ca), molybdenum (Mo), titanium (Ti), tungsten (W), and/or copper (Cu), and may include a single layer or a multi-layer including the above materials.

The first interlayer insulating layer 113 may be disposed on the first gate electrode G1 and/or the first capacitor electrode CE1. The first interlayer insulating layer 113 may include an inorganic insulating layer including an inorganic insulating material such as silicon oxide, silicon nitride and/or silicon oxynitride, and may include a single layer or a multi-layered structure including the above material.

The second capacitor electrode CE2 may be disposed on the first interlayer insulating layer 113. The second capacitor electrode CE2 may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and may include a single layer or a multi-layer including the above materials. The second capacitor electrode CE2 may overlap the first gate electrode G1 and/or the first capacitor electrode CE1 in a third direction (e.g., z-axis direction) perpendicular the first direction (e.g., x-axis direction) and the second direction (e.g., y-axis direction). The second capacitor electrode CE2 may include a hole CE2-H for connection between a node connection electrode 171 and the first gate electrode G1. The node connection electrode 171 may be for electric connection between the first gate electrode G1 of the driving transistor T1 and the compensation transistor T3. The hole CE2-H may overlap a portion of the first gate electrode G1.

The second interlayer insulating layer 114 may be disposed on the second capacitor electrode CE2. The second interlayer insulating layer 114 may include an inorganic insulating layer including an inorganic insulating material such as silicon oxide, silicon nitride and/or silicon oxynitride, and may include a single layer or a multi-layered structure including the above material.

Oxide semiconductor layers may be disposed on the second interlayer insulating layer 114. FIG. 4 shows a third semiconductor layer A3 of the compensation transistor T3 corresponding to a portion of a first oxide semiconductor pattern layer OSL1. The third semiconductor layer A3 may include a third channel region C3, and conductive regions arranged on two opposite sides of the third channel region C3. FIG. 4 shows a second region D3, which is one of the conductive regions arranged on a side of the third channel region C3. A vertical distance between the substrate 100 to the third semiconductor layer A3 may be greater than a vertical distance between the substrate 100 to the first semiconductor layer A1.

A third gate electrode G3 may be disposed under and/or on the third semiconductor layer A3. In an embodiment, referring to FIG. 4, the third gate electrode G3 may include a third lower gate electrode G3a and a third upper gate electrode G3b. The third lower gate electrode G3a may be disposed below the third semiconductor layer A3, and the third upper gate electrode G3b may be disposed over the third semiconductor layer A3. In another embodiment, one of the third lower gate electrode G3a and the third upper gate electrode G3b may be omitted.

The third lower gate electrode G3a and the second capacitor electrode CE2 may include the same material, and may be arranged on the same layer (e.g., the first interlayer insulating layer 113). The third upper gate electrode G3b may be disposed over the third semiconductor layer A3. The second gate insulating layer 115 may be disposed between the third upper gate electrode G3b and the third semiconductor layer A3. The third upper gate electrode G3b may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and may include a single layer or a multi-layer including the above materials.

Though it is shown in FIG. 4 that the second gate insulating layer 115 is disposed only between the third upper gate electrode G3b and the third semiconductor layer A3, embodiments are not limited thereto. In another embodiment, like another insulating layer (e.g., the first gate insulating layer 112), the second gate insulating layer 115 may be formed to cover (e.g., entirely cover) the substrate 100. The second gate insulating layer 115 may include an inorganic insulating layer including an inorganic insulating material such as silicon oxide, silicon nitride and/or silicon oxynitride, and may include a single layer or a multi-layered structure including the above material.

The third interlayer insulating layer 116 may be disposed on the third upper gate electrode G3b. The third interlayer insulating layer 116 may include an inorganic insulating layer including an inorganic insulating material such as silicon oxide, silicon nitride and/or silicon oxynitride, and may include a single layer or a multi-layered structure including the above material.

The node connection electrode 171 and a first connection electrode NM1 may be disposed on the third interlayer insulating layer 116. The node connection electrode 171 and the first connection electrode NM1 may include aluminum (Al), platinum (Pt), palladium (Pd), silver (Ag), magnesium (Mg), gold (Au), Nickel (Ni), neodymium (Nd), iridium (Ir), chrome (Cr), lithium (Li), calcium (Ca), molybdenum (Mo), titanium (Ti), tungsten (W), and/or copper (Cu), and may include a single layer or a multi-layer including the above materials. In an example, the node connection electrode 171 may have a triple-layered structure in which a titanium layer, an aluminum layer, and a titanium layer are stacked.

The first connection electrode NM1 may connect (e.g., electrically connect) the first semiconductor layer A1 to the third semiconductor layer A3. The first connection electrode NM1 may be connected (e.g., electrically connected) to a portion (e.g., the second region D1 of FIG. 4) of the first semiconductor layer A1 through a first contact hole CNT1, and connected (e.g., electrically connected) to a portion (e.g., the second region D3 of FIG. 4) of the third semiconductor layer A3 through a second contact hole CNT2. The first contact hole CNT1 may pass through inorganic insulating layers, for example, the first gate insulating layer 112, the first interlayer insulating layer 113, the second interlayer insulating layer 114, and the third interlayer insulating layer 116 disposed between the first semiconductor layer A1 and the first connection electrode NM1. The second contact hole CNT2 may pass through the third interlayer insulating layer 116 disposed between the third semiconductor layer A3 and the first connection electrode NM1.

The bottom metal layer BML may have a voltage level of a constant voltage. The bottom metal layer BML may prevent or reduce occurrence of an afterimage due to negative charges by preventing the negative charges from gathering at the lower portion of the first semiconductor layer A1 of the driving transistor T1.

A first organic insulating layer 121 may be formed on the first connection electrode NM1 and the node connection electrode 171. The first organic insulating layer 121 may include an organic material such as acryl, benzocyclobutene (BCB), polyimide, or hexamethyldisiloxane (HMDSO).

The driving voltage line PL may be disposed on the first organic insulating layer 121. The second organic insulating layer 123 may be disposed on the driving voltage line PL. The driving voltage line PL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), and/or tungsten (W). In an embodiment, the driving voltage line PL may have a triple-layered structure of a titanium layer, an aluminum layer, and a titanium layer.

The second organic insulating layer 123 may include an organic material such as benzocyclobutene (BCB), polyimide, or hexamethyldisiloxane (HMDSO).

The light-emitting diode layer DEL may be disposed on the sub-pixel circuit layer PCL. The light-emitting diode layer DEL may include a light-emitting diode. In an example, the light-emitting diode layer DEL may include an organic light-emitting diode OLED. The organic light-emitting diode OLED may include a sub-pixel electrode 210, an emission layer 220, and an opposite electrode 230.

The sub-pixel electrode 210 of the organic light-emitting diode OLED may be formed on the second organic insulating layer 123. The emission layer 220 may include a low-molecular weight organic material or a polymer organic material. At least one of a hole injection layer (HIL), a hole transport layer (HTL), an electron transport layer (ETL), and an electron injection layer (EIL) may be further disposed between the sub-pixel electrode 210 and the opposite electrode 230.

The edge portions of the sub-pixel electrode 210 may be covered by a bank layer 130, and the inner portion of the sub-pixel electrode 210 may overlap the emission layer 220 through an opening 130OP of the bank layer 130. In case that the sub-pixel electrode 210 is formed for each organic light-emitting diode OLED, the opposite electrode 230 may be formed to correspond to organic light-emitting diodes OLED. For example, the organic light-emitting diodes OLED may share the opposite electrode 230. A stack structure of the sub-pixel electrode 210, the emission layer 220, and a portion of the opposite electrode 230 may correspond to the organic light-emitting diode OLED.

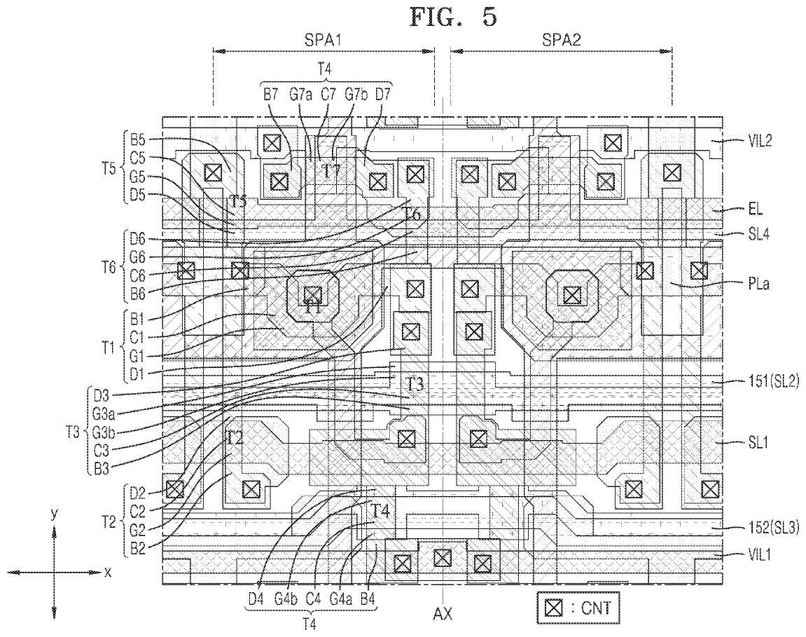

An encapsulation layer 300 may be disposed on the organic light-emitting diode OLED. The encapsulation layer 300 may include at least one inorganic encapsulation layer and at least one organic encapsulation layer. Referring to FIG. 5, the encapsulation layer 300 may include a first inorganic encapsulation layer 310, an organic encapsulation layer 320, and a second inorganic encapsulation layer 330. The first inorganic encapsulation layer 310 and the second inorganic encapsulation layer 330 may each include silicon oxide, silicon nitride, and/or silicon oxynitride. The organic encapsulation layer 320 may include an organic insulating material.

FIG. 5 is a schematic plan view of positions of elements arranged in a sub-pixel circuit of the display apparatus 10 according to an embodiment. FIG. 5 is a portion of FIG. 3 and shows two sub-pixel circuit areas SPA arranged in the same row and adjacent to each other. In an example, FIG. 5 shows a first sub-pixel circuit area SPA1 and a second sub-pixel circuit area SPA2.

A sub-pixel circuit in the first sub-pixel circuit area SPA1 and a sub-pixel circuit in the second sub-pixel circuit area SPA2 may have a left-right symmetrical structure around a virtual line AX between the first sub-pixel circuit area SPA1 and the second sub-pixel circuit area SPA2.

Referring to FIG. 5, each of the sub-pixel circuits may include thin-film transistors and capacitors. In an example, each of the sub-pixel circuits may include the driving transistor T1. the switching transistor T2, the compensation transistor T3, the first initialization transistor T4, the operation control transistor T5, the emission control transistor T6, the second initialization transistor T7, the first capacitor Cst, and the second capacitor Cbt. In an embodiment, the driving transistor T1, the switching transistor T2, the operation control transistor T5, and the emission control transistor T6 may each include a thin-film transistor including a silicon semiconductor, and the compensation transistor T3, the first initialization transistor T4, and the second initialization transistor T7 may each include a thin-film transistor including an oxide semiconductor.

The sub-pixel circuits may each be connected (e.g., electrically connected) to signal lines, the driving voltage line PL, the first initialization voltage line VIL1, and the second initialization voltage line VIL2 extending in the first direction (e.g., the x-axis direction) or the second direction (e.g., the y-axis direction) intersecting the first direction. The signal lines may include the data line DL, the emission control line EL, the first scan line SL1, the second scan line SL2, the third scan line SL3, and the fourth scan line SL4. At least one of the signal lines, the first and second initialization voltage lines VIL1 and VIL2, and the driving voltage line PL may be shared by adjacent sub-pixel circuits.

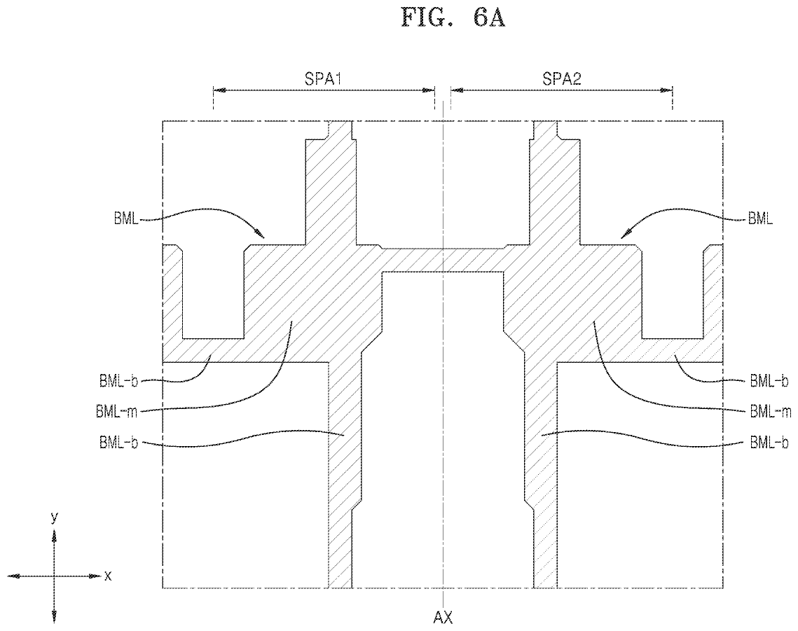

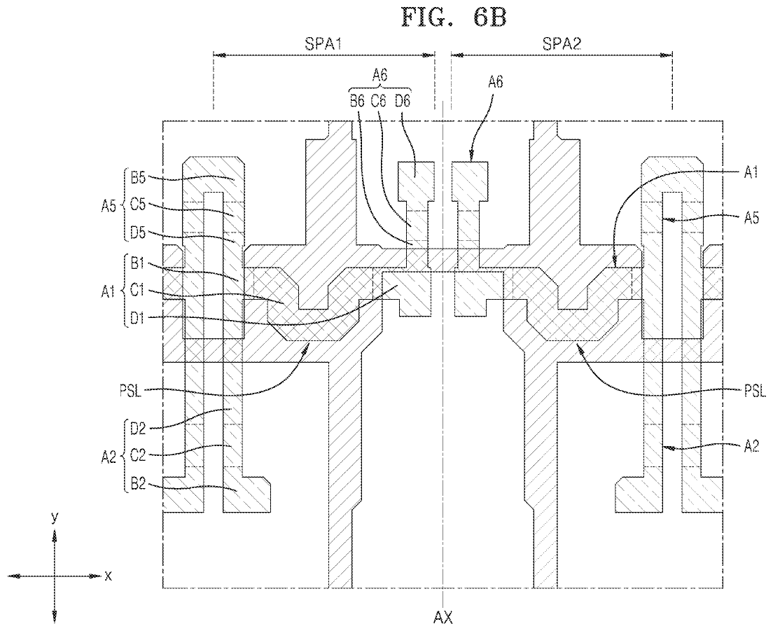

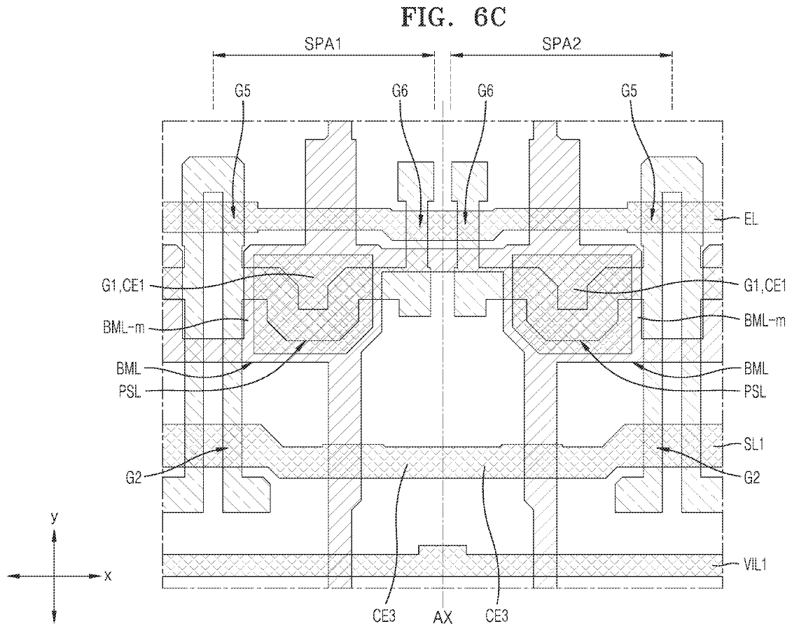

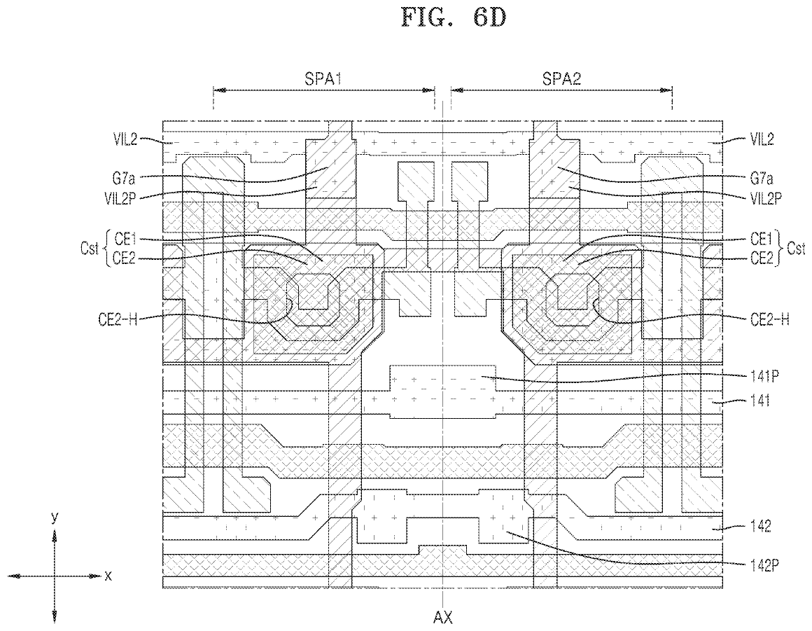

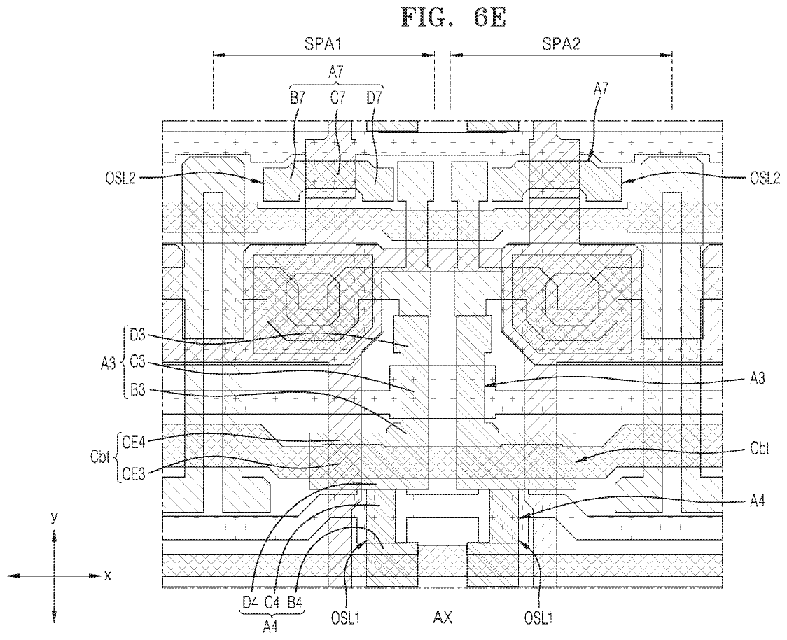

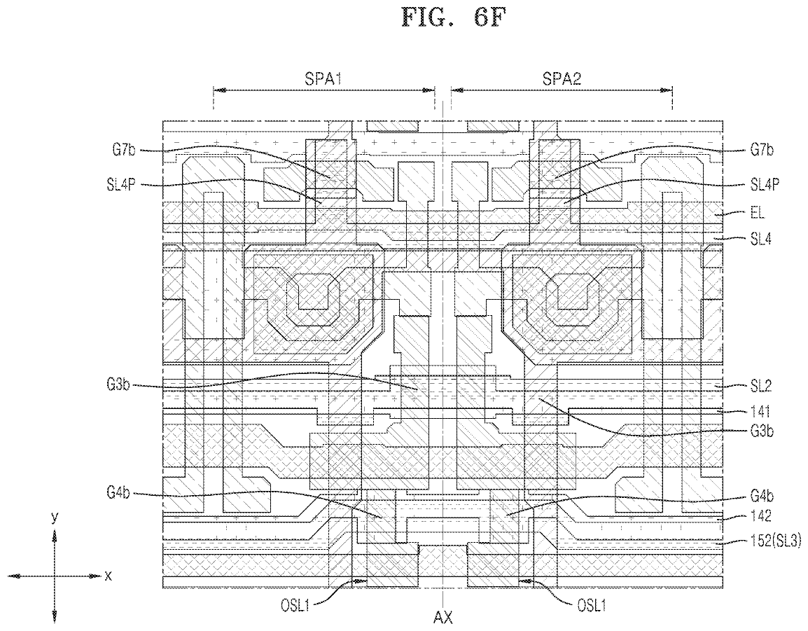

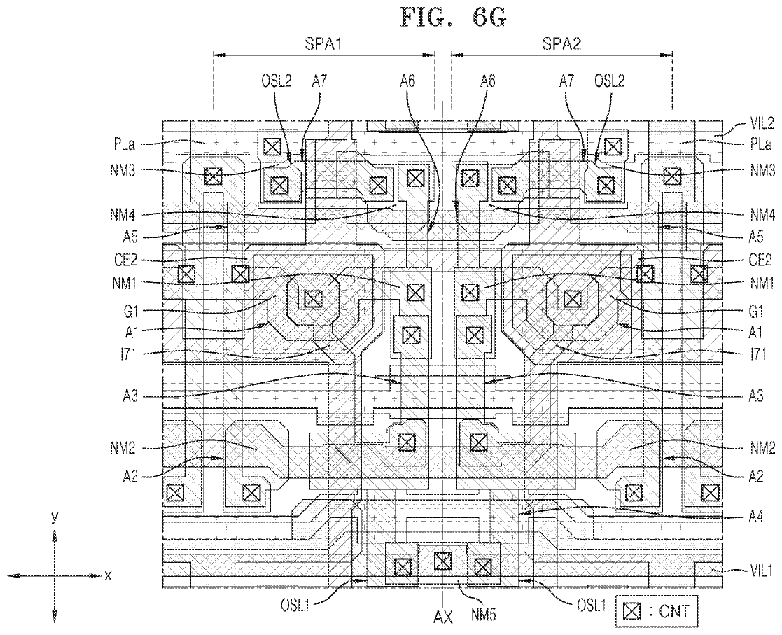

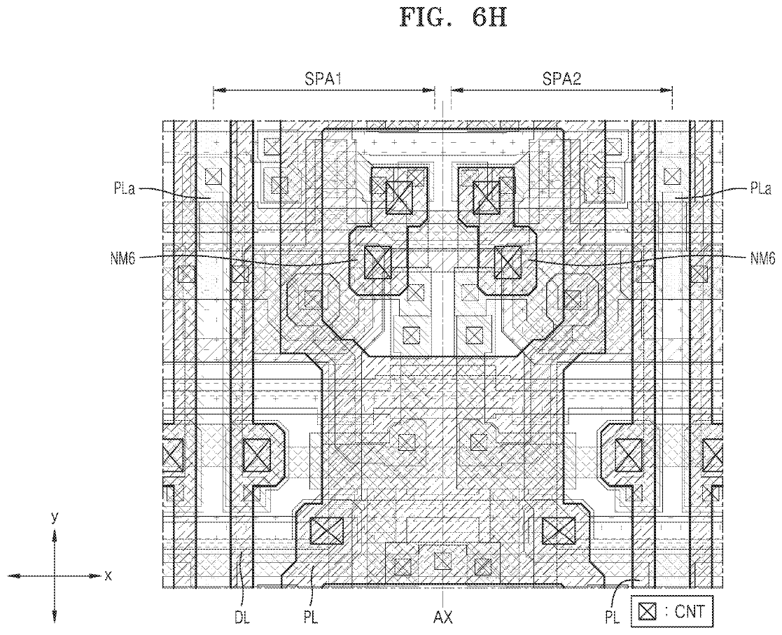

FIGS. 6A to 6H are schematic plan views showing a process of forming elements arranged in the sub-pixel circuit of the display apparatus 10 according to an embodiment.

Referring to FIGS. 4, 5, and 6A, the bottom metal layer BML may be formed on the substrate 100 (see FIG. 4). The bottom metal layer BML may include the material described above with reference to FIG. 4. In an example, the bottom metal layer BML may include metal such as molybdenum, titanium, and aluminum. The bottom metal layer BML may be, for example, a single layer of molybdenum, a double layer of molybdenum and titanium, or a triple layer of a titanium layer, an aluminum layer, and a titanium layer.

As shown in FIG. 6A, the bottom metal layer BML may include a portion (referred to as a main portion BML-m, hereinafter) positioned in each of the first and second sub-pixel circuit areas SPA1 and SPA2. Each main portion BML-m may be connected (e.g., electrically connected) to other portions (referred to as branch portions BML-b, hereinafter) extending in the x-axis direction and the y-axis direction.

The bottom metal layer BML arranged in the first and second sub-pixel circuit areas SPA1 and SPA2 may be substantially symmetrical with respect to the virtual line AX between the first and second sub-pixel circuit areas SPA1 and SPA2. The main portion BML-m arranged in the first sub-pixel circuit area SPA1 may be connected (e.g., directly connected) to the main portion BML-m arranged in the second sub-pixel circuit area SPA2.

Referring to FIGS. 4, 5, and 6B, the buffer layer 111 (see FIG. 4) may be formed on the bottom metal layer BML, and a silicon semiconductor pattern layer may be formed on the buffer layer 111. FIG. 6B shows the silicon semiconductor pattern layer PSL arranged in each of the first and second sub-pixel circuit areas SPA1 and SPA2. The silicon semiconductor pattern layer PSL arranged in the first sub-pixel circuit area SPA1 and the silicon semiconductor pattern layer PSL arranged in the second sub-pixel circuit area SPA2 may be substantially symmetrical with respect to the virtual line AX. The silicon semiconductor pattern layer PSL may include a silicon-based material, for example, polycrystalline silicon.

The silicon semiconductor pattern layer PSL may be bent in various shapes, and as shown in FIG. 6B, the first semiconductor layer A1 of the driving transistor T1, a second semiconductor layer A2 of the switching transistor T2, a fifth semiconductor layer A5 of the operation control transistor T5, and a sixth semiconductor layer A6 of the emission control transistor T6 may be arranged along the silicon semiconductor pattern layer PSL. For example, the silicon semiconductor pattern layer PSL may include the first semiconductor layer A1, the second semiconductor layer A2, the fifth semiconductor layer A5, and the sixth semiconductor layer A6. The first semiconductor layer A1, the second semiconductor layer A2, the fifth semiconductor layer A5, and the sixth semiconductor layer A6 may be connected (e.g., electrically connected) to each other, and may be formed as a single body.

The first semiconductor layer A1 may include a first channel region C1, a first region B1, and a second region D1. The first region B1 and the second region D1 may be disposed on two opposite sides of the first channel region C1. The first and second regions B1 and D1 of the first semiconductor layer A1 may be regions doped with impurities, and may have greater electrical conductivity than that of the first channel region C1. One of the first and second regions B1 and D1 may be a source region and the other may be a drain region. The first channel region C1 may have a bent shape (e.g., a bent shape of an omega shape) in a plan view. The length of the first channel region C1 may be increased inside a narrow space according to the above-described shape.

The first semiconductor layer A1 may overlap the bottom metal layer BML. As an example, the first channel region C1 of the first semiconductor layer A1 may overlap the bottom metal layer BML. In an example, the first channel region C1 of the first semiconductor layer A1 may overlap a main portion BML-m which is a portion of the bottom metal layer BML.

The second semiconductor layer A2 may include a second channel region C2, a first region B2, and a second region D2. The first region B2 and the second region D2 may be disposed on two opposite sides of the second channel region C2. The first and second regions B2 and D2 of the second semiconductor layer A2 may be regions doped with impurities, and may have greater electrical conductivity than that of the second channel region C2. One of the first and second regions B2 and D2 may be a source region and the other may be a drain region.

The fifth semiconductor layer A5 may include a fifth channel region C5, a first region B5, and a second region D5. The first region B5 and the second region D5 may be disposed on two opposite sides of the fifth channel region C5. The first and second regions B5 and D5 of the fifth semiconductor layer A5 may be regions doped with impurities, and may have greater electrical conductivity than that of the fifth channel region C5. One of the first and second regions B5 and D5 may be a source region and the other may be a drain region.

The sixth semiconductor layer A6 may include a sixth channel region C6, a first region B6, and a second region D6. The first region B6 and the second region D6 may be disposed on two opposite sides of the sixth channel region C6. The first and second regions B5 and D5 of the sixth semiconductor layer A6 may be regions doped with impurities, and may have greater electrical conductivity than that of the sixth channel region C6. One of the first and second regions B6 and D6 may be a source region and the other may be a drain region.

In an embodiment, the first region B1 of the first semiconductor layer A1 may be connected, as one body (or single body), to the second region D2 of the second semiconductor layer A2 and the second region D5 of the fifth semiconductor layer A5. The second region D1 of the first semiconductor layer A1 may be connected, as one body (or single body), to the first region B6 of the sixth semiconductor layer A6.

Referring to FIGS. 4, 5, and 6C, the first gate insulating layer 112 (see FIG. 4) may be formed on the silicon semiconductor pattern layer PSL, the first gate electrode G1 of the driving transistor T1, a second gate electrode G2 of the switching transistor T2, a fifth gate electrode G5 of the operation control transistor T5, and a sixth gate electrode G6 of the emission control transistor T6 may be disposed on the first gate insulating layer 112. The first capacitor electrode CE1, the first scan line SL1, the emission control line EL, and the first initialization voltage line VIL1 may be disposed on the first gate insulating layer 112.

The first gate electrode G1 may have an isolated shape in a plan view and may include the first capacitor electrode CE1. For example, the first gate electrode G1 and the first capacitor electrode CE1 may be formed as one body (or single body), and the first capacitor electrode CE1 may include the first gate electrode G1.

The first gate electrode G1 and/or the first capacitor electrode CE1 may be formed to cover (e.g., entirely cover) the first channel region C1 of the first semiconductor layer A1. The main portion BML-m of the bottom metal layer BML may have a greater area than that of the first gate electrode G1 and/or the first capacitor electrode CE1. The main portion BML-m of the bottom metal layer BML may overlap (e.g., entirely overlap) the first channel region C1 of the first semiconductor layer A1.

The first gate electrode G1 and/or the first capacitor electrode CE1 arranged in each of the first and second sub-pixel circuit areas SPA1 and SPA2 may be substantially symmetrical with respect to the virtual line AX between the first and second sub-pixel circuit areas SPA1 and SPA2. The first scan line SL1 arranged in the first and second sub-pixel circuit areas SPA1 and SPA2 may be substantially symmetrical with respect to the virtual line AX. The emission control line EL arranged in the first and second sub-pixel circuit areas SPA1 and SPA2 may be substantially symmetrical with respect to the virtual line AX. The first initialization voltage line VIL1 arranged in the first and second sub-pixel circuit areas SPA1 and SPA2 may be substantially symmetrical with respect to the virtual line AX. The first scan line SL1, the emission control line EL, and the first initialization voltage line VIL1 may each extend in the x-axis direction to pass across the first and second sub-pixel circuit areas SPA1 and SPA2. The first scan line SL1, the emission control line EL, and the first initialization voltage line VIL1 may be spaced apart from each other. The first gate electrode G1 and/or the first capacitor electrode CE1 may be disposed between the first scan line SL1, the emission control line EL. and the first initialization voltage line VIL1 in a plan view.

The first scan line SL1 may include the second gate electrode G2 and the third capacitor electrode CE3. The emission control line EL may include the fifth gate electrode G5 and the sixth gate electrode G6.

The first scan line SL1, the emission control line EL, the first initialization voltage line VIL1 may each include the same material as that of the first gate electrode G1 and/or the first capacitor electrode CE1, and a specific material thereof is the same as that described above with reference to FIG. 4.

Referring to FIGS. 4, 5, and 6D, the first interlayer insulating layer 113 (see FIG. 4) may be formed on the structure of FIG. 6C, and the second capacitor electrode CE2, a third lower gate line 141, and a fourth lower gate line 142, and the second initialization voltage line VIL2 may be formed.

The second capacitor electrode CE2 may overlap the first capacitor electrode CE1, and may include a hole CE2-H that exposes a portion of the first capacitor electrode CE1. In a plan view, the hole CE2-H may have a structure surrounded (e.g., entirely surrounded) by a material portion forming the second capacitor electrode CE2. For example, the second capacitor electrode CE2 may have a doughnut shape (or a ring shape) in a plan view. The first capacitor electrode CE1 and the second capacitor electrode CE2 may form the first capacitor Cst. The second capacitor electrodes CE2 respectively arranged in the first and second sub-pixel circuit areas SPA1 and SPA2 may be integrally connected to each other (or integral with each other).

The third lower gate line 141 may include a main portion and a protrusion 141P. The main portion of the third lower gate line 141 may extend in the x-axis direction, and the protrusion 141P may extend from the main portion in the y-axis direction perpendicular to the x-axis direction. The protrusion 141P may be disposed to cover (e.g., entirely cover) the third channel region C3 of the third semiconductor layer A3 below the third semiconductor layer A3 (see FIG. 5) and may block light introduced (or incident) from below the substrate 100. The protrusion 141P may include the third lower gate electrode G3a. The third lower gate line 141 arranged in the first and second sub-pixel circuit areas SPA1 and SPA2 may have a substantially symmetrical shape with respect to the virtual line AX.

The fourth lower gate line 142 may include a main portion and a protrusion 142P. The main portion of the fourth lower gate line 142 may extend in the x-axis direction, and the protrusion 141P may extend from the main portion in the y-axis direction perpendicular to the x-axis direction. The protrusion 142P may be disposed to cover (e.g., entirely cover) a fourth channel region C4 of a fourth semiconductor layer A4 below the fourth semiconductor layer A4 (see FIG. 5) and may block light introduced (or incident) from below the substrate 100. The protrusion 142P may include a fourth lower gate electrode G4a. The fourth lower gate line 142 arranged in the first and second sub-pixel circuit areas SPA1 and SPA2 may have a substantially symmetrical shape with respect to the virtual line AX.

The second initialization voltage line VIL2 may include a main portion and a protrusion VIL2P. The main portion of the second initialization voltage line VIL2 may extend in the x-axis direction, and the protrusion VIL2P may extend from the main portion in the y-axis direction perpendicular to the x-axis direction. Similarly to the protrusion 141P of the third lower gate line 141 and the protrusion 142P of the fourth lower gate line 142, the protrusion VIL2P may be disposed to cover (e.g., entirely cover) a seventh channel region C7 of a seventh semiconductor layer A7 below the seventh semiconductor layer A7 (see FIG. 5) and may block light that may be introduced (or incident) from below the substrate 100. The protrusion VIL2P may include a seventh lower gate electrode G7a. For example, the seventh lower gate electrode G7a may be a portion extending in the y-axis direction from the second initialization voltage line VIL2 extending in the x-axis direction. The second initialization voltage line VIL2 arranged in the first and second sub-pixel circuit areas SPA1 and SPA2 may have a substantially symmetrical shape with respect to the virtual line AX.

The second capacitor electrode CE2, the third lower gate line 141, the fourth lower gate line 142, and the second initialization voltage line VIL2 may include the same material, and be disposed on the same layer (e.g., the first interlayer insulating layer 113 in FIG. 4). The third lower gate line 141 and the fourth lower gate line 142 may include the same material as that of the second capacitor electrode CE2 described above with reference to FIG. 4.

Referring to FIGS. 4, 5, and 6E, the second interlayer insulating layer 114 (see FIG. 4) may be formed on the structure of FIG. 6D, and a first oxide semiconductor pattern layer OSL1 and a second oxide semiconductor pattern layer OSL2 may be formed on the second interlayer insulating layer 114. The first oxide semiconductor pattern layer OSL1 and the second oxide semiconductor pattern layer OSL2 respectively arranged in the first and second sub-pixel circuit areas SPA1 and SPA2 may be symmetrical with respect to the virtual line AX between the first and second sub-pixel circuit areas SPA1 and SPA2.

The first oxide semiconductor pattern layer OSL1 and the second oxide semiconductor pattern layer OSL2 may include an oxide-based semiconductor material, for example, Zn-oxide, In—Zn oxide, and Ga—In—Zn oxide. In an embodiment, the first oxide semiconductor pattern layer OSL1 and the second oxide semiconductor pattern layer OSL2 may include an In—Ga—Zn—O (IGZO) semiconductor, an In—Sn—Zn—O (ITZO) semiconductor, or an In—Ga—Sn—Zn—O (IGTZO) semiconductor containing metal such as indium (In), gallium (Ga), and tin (Sn) in ZnO.

The first oxide semiconductor pattern layer OSL1 and the second oxide semiconductor pattern layer OSL2 may include the same material. For example, the third semiconductor layer A3, the fourth semiconductor layer A4, and the seventh semiconductor layer A7 may include the same material. The first oxide semiconductor pattern layer OSL1 may be spaced apart from the second oxide semiconductor pattern layer OSL2.

The first oxide semiconductor pattern layer OSL1 may include the third semiconductor layer A3 of the compensation transistor T3 and the fourth semiconductor layer A4 of the first initialization transistor T4. The third semiconductor layer A3 and the fourth semiconductor layer A4 may be connected (e.g., electrically connected) to each other and formed as one body (or single body).

The third semiconductor layer A3 may include the third channel region C3, a first region B3, and a second region D3. The first region B3 and the second region D3 may be disposed on two opposite sides of the third channel region C3. The first and second regions B3 and D3 of the third semiconductor layer A3 may be regions doped with impurities, and may have greater electrical conductivity than that of the third channel region C3. One of the first and second regions B3 and D3 may be a source region and the other may be a drain region.

The fourth semiconductor layer A4 may include the fourth channel region C4, a first region B4, and a second region D4. The first region B4 and the second region D4 may be disposed on two opposite sides of the fourth channel region C4. The first and second regions B4 and D4 of the fourth semiconductor layer A4 may be regions made conductive, and may have greater electrical conductivity than that of the fourth channel region C4. One of the first and second regions B4 and D4 may be a source region and the other may be a drain region.

The first oxide semiconductor pattern layer OSL1 may include the fourth capacitor electrode CE4. A portion of the first oxide semiconductor pattern layer OSL1 that overlaps the third capacitor electrode CE3 (see FIG. 6E) may correspond to the fourth capacitor electrode CE4. For example, the fourth capacitor electrode (e.g., upper electrode) CE4 of the second capacitor Cbt may extend from the third semiconductor layer A3 of the compensation transistor T3 (e.g., a portion of the first oxide semiconductor pattern layer OSL1 in FIG. 6E). The fourth capacitor electrode (e.g., upper electrode) CE4 of the second capacitor Cbt and the third semiconductor layer A3 of the compensation transistor T3 may be disposed on the same layer (e.g., the second interlayer insulating layer 114 in FIG. 4). For example, the third capacitor electrode (e.g., lower electrode) CE3 of the second capacitor Cbt may be integral with the second gate electrode G2 of the switching transistor T2, and the third capacitor electrode CE3 may overlap the first oxide semiconductor pattern layer OSL1. The third capacitor electrode (e.g., lower electrode) CE3 of the second capacitor Cbt, the second gate electrode G2 of the switching transistor T2, and the first gate electrode G1 of the driving transistor T1 may be disposed on the same layer (e.g., the first gate insulating layer 112 in FIG. 4). The third capacitor electrode CE3 and the fourth capacitor electrode CE4 may form the second capacitor Cbt.

The second oxide semiconductor pattern layer OSL2 may include the seventh semiconductor layer A7. The seventh semiconductor layer A7 may include the seventh channel region C7, a first region B7, and a second region D7. The first region B7 and the second region D7 may be disposed on two opposite sides of the seventh channel region C7. The first and second regions B7 and D7 of the seventh semiconductor layer A7 may be regions doped with impurities, and may have greater electrical conductivity than that of the seventh channel region C7. One of the first and second regions B7 and D7 may be a source region and the other may be a drain region.

Referring to FIGS. 4, 5, and 6F, a third upper gate line 151, a fourth upper gate line 152, and a fourth scan line SL4 may be formed on the structure of FIG. 6D. The third upper gate line 151 may be the second scan line SL2. The fourth upper gate line 152 may be the third scan line SL3.

Each of the third upper gate line 151 and the fourth upper gate line 152 may extend in the x-axis direction. The third upper gate line 151 arranged in the first and second sub-pixel circuit areas SPA1 and SPA2 may have a substantially symmetrical shape with respect to the virtual line AX. The fourth upper gate line 152 arranged in the first and second sub-pixel circuit areas SPA1 and SPA2 may have a substantially symmetrical shape with respect to the virtual line AX.

At least a portion of the third upper gate line 151 may overlap the third lower gate line 141, e.g., the protrusion 141P. The first oxide semiconductor pattern layer OSL1 may be disposed between the at least a portion of the third upper gate line 151 and the third lower gate line 141. The third upper gate line 151 may include the third upper gate electrode G3b. The third upper gate electrode G3b may overlap the third lower gate electrode G3a. The third semiconductor layer A3 of the first oxide semiconductor pattern layer OSL1 may be disposed between the third upper gate electrode G3b and the third lower gate electrode G3a.

At least a portion of the fourth upper gate line 152 may overlap the fourth lower gate line 142, e.g., the protrusion 142P. The first oxide semiconductor pattern layer OSL1 may be disposed between the at least a portion of the fourth upper gate line 152 and the fourth lower gate line 142. The fourth upper gate line 152 may include the fourth upper gate electrode G4b. The fourth upper gate electrode G4b may overlap the fourth lower gate electrode G4a. The fourth semiconductor layer A4 of the first oxide semiconductor pattern layer OSL1 may be disposed between the fourth upper gate electrode G4b and the fourth lower gate electrode G4a.

The fourth scan line SL4 may include a main portion and a protrusion SL4P. The main portion of the fourth scan line SL4 may extend in the x-axis direction, and the protrusion SL4P may extend from the main portion in the y-axis direction perpendicular to the x-axis direction. The protrusion SLAP may include a seventh upper gate electrode G7b. For example, the seventh upper gate electrode G7b may be a portion extending in the y-axis direction from the fourth scan line SL4 extending in the x-axis direction. The fourth scan line SL4 arranged in the first and second sub-pixel circuit areas SPA1 and SPA2 may have a substantially symmetrical shape with respect to the virtual line AX. The protrusion SL4P of the fourth scan line SL4 may overlap the protrusion VIL2P of the second initialization voltage line VIL2. The seventh semiconductor layer A7 of the second oxide semiconductor pattern layer OSL2 may be disposed between the protrusion SLAP of the fourth scan line SL4 and the protrusion VIL2P of the second initialization voltage line VIL2.

The third upper gate line 151, the fourth upper gate line 152, and the fourth scan line SL4 may include the same material as a material of the third upper gate electrode G3b described above with reference to FIG. 4.

Referring to FIGS. 4, 5, and 6G, the third interlayer insulating layer 116 (see FIG. 4) may be formed on the structure of FIG. 6F. For example, first to fifth connection electrodes NM1, NM2, NM3, NM4, and NM5, the node connection electrode 171, and an auxiliary driving voltage line PLa may be formed.

The first connection electrode NM1 may electrically connect the first semiconductor layer A1 of the silicon semiconductor pattern layer PSL to the third semiconductor layer A3 of the first oxide semiconductor pattern layer OSL1. The first connection electrode NM1 may be connected (e.g., electrically connected) to the second region D3 (see FIG. 5), which a portion of the first semiconductor layer A1, through a contact hole CNT, and connected (e.g., electrically connected) to the second region D3 (see FIG. 5), which is a portion of the third semiconductor layer A3, through a contact hole CNT. The second connection electrode NM2 may be connected (e.g., electrically connected) to the first region B2 (see FIG. 5), which is a portion of the second semiconductor layer A2.

An end portion of the node connection electrode 171 may be connected (e.g., electrically connected) to the first gate electrode G1 through a hole CE2-H (see FIG. 6D) of the second capacitor electrode CE2, and another end may be connected (e.g., electrically connected) to the third semiconductor layer A3.

The auxiliary driving voltage line PLa may be connected (e.g., electrically connected) to the first region B5 (see FIG. 5), which is a portion of the fifth semiconductor layer A5, through a contact hole CNT and electrically connected to the second capacitor electrode CE2 through a contact hole CNT.

The third connection electrode NM3 may electrically connect the second initialization voltage line VIL2 to the seventh semiconductor layer A7 of the second oxide semiconductor pattern layer OSL2. The third connection electrode NM3 may be connected (e.g., electrically connected) to the second initialization voltage line VIL2 through a contact hole CNT. The third connection electrode NM3 may be connected (e.g., electrically connected) to the first region B7 (see FIG. 5), which is a portion of the seventh semiconductor layer A7, through a contact hole CNT.

The fourth connection electrode NM4 may electrically connect the sixth connection electrode NM6 (see FIG. 6F) to the seventh semiconductor layer A7 of the second oxide semiconductor pattern layer OSL2. The fourth connection electrode NM4 may be connected (e.g., electrically connected) to the sixth connection electrode NM6 (see FIG. 6F) through a contact hole CNT. The fourth connection electrode NM4 may be connected (e.g., electrically connected) to the second region D7 (see FIG. 5), which is a portion of the seventh semiconductor layer A7, through a contact hole CNT.

The fifth connection electrode NM5 may extend in the x-axis direction and be arranged in the first and second sub-pixel circuit areas SPA1 and SPA2. The fifth connection electrode NM5 arranged in the first and second sub-pixel circuit areas SPA1 and SPA2 may have a substantially symmetrical shape with respect to the virtual line AX. The fifth connection electrode NM5 may electrically connect the first initialization voltage line VIL1 to the fourth semiconductor layer A4 of the first oxide semiconductor pattern layer OSL1. The fifth connection electrode NM5 may be connected (e.g., electrically connected) to the first initialization voltage line VIL1 through a contact hole CNT. The fifth connection electrode NM5 may be connected (e.g., electrically connected) to the first region B4 (see FIG. 5), which is a portion of the fourth semiconductor layer A4, through a contact hole CNT.

The first to fifth connection electrodes NM1, NM2, NM3, NM4, and NM5, the node connection electrode 171, and the auxiliary driving voltage line PLa may include the same material. In an example, the second to fifth connection electrodes NM2, NM3, NM4, and NM5, and the auxiliary driving voltage line PLa may include the same material as a material of the first connection electrode NM1 and the node connection electrode 171. In an example, the first to fifth connection electrodes NM1, NM2, NM3, NM4, and NM5, the node connection electrode 171, and the auxiliary driving voltage line PLa may have a triple-layered structure in which a titanium layer, an aluminum layer, and a titanium layer are stacked.

Referring to FIGS. 4, 5, and 6H, the first organic insulating layer 121 (see FIG. 4) may be formed on the structure of FIG. 6F, and the data line DL, the driving voltage line PL, and the sixth connection electrode NM6 may be formed.

The data line DL and the driving voltage line PL may each extend in the y-axis direction. The data lines DL respectively arranged in the first and second sub-pixel circuit areas SPA1 and SPA2 may be connected (e.g., electrically connected) to the second connection electrode NM2 through a contact hole CNT. Each data line DL may be electrically connected to the second semiconductor layer A2 of the switching transistor T2 through the second connection electrode NM2 in FIG. 6G.

The driving voltage line PL may be connected (e.g., electrically connected) to the auxiliary driving voltage line PLa through a contact hole CNT. The driving voltage line PL may be electrically connected to the first region B5 (see FIG. 5), which is a portion of the fifth semiconductor layer A5, and the second capacitor electrode CE2, through the auxiliary driving voltage line PLa. Because the second capacitor electrode CE2 and a portion of the auxiliary driving voltage line PLa extend in the x-axis direction, the second capacitor electrode CE2 and a portion of the auxiliary driving voltage line PLa may transfer the driving voltage ELVDD in the x-axis direction.

The sixth connection electrode NM6 may electrically connect the sub-pixel electrode of the light-emitting diode to the fourth connection electrode NM4. The sixth connection electrode NM6 may be connected (e.g., electrically connected) to the sub-pixel electrode of the light-emitting diode through a contact hole CNT. The sixth connection electrode NM6 may be connected (e.g., electrically connected) to the fourth connection electrode NM4 through a contact hole CNT in FIG. 6G. The sub-pixel electrode of the light-emitting diode may be electrically connected to the second region D6 (see FIG. 5), which is a portion of the sixth semiconductor layer A6 of the emission control transistor T6, through the fourth connection electrode NM4 and the sixth connection electrode NM6.

The data line DL, the driving voltage line PL, and the sixth connection electrode NM6 may each include aluminum (Al), platinum (Pt), palladium (Pd), silver (Ag), magnesium (Mg), gold (Au), Nickel (Ni), neodymium (Nd), iridium (Ir), chrome (Cr), lithium (Li), calcium (Ca), molybdenum (Mo), titanium (Ti), tungsten (W), and/or copper (Cu), and may include a single layer or a multi-layer including the above materials. The data line DL and the sixth connection electrode NM6 may include the same material as a material of the driving voltage line PL described above with reference to FIG. 4. In an example, the data line DL, the sixth connection electrode NM6, and the driving voltage line PL may each have a structure in which a titanium layer, an aluminum layer, and a titanium layer are stacked.

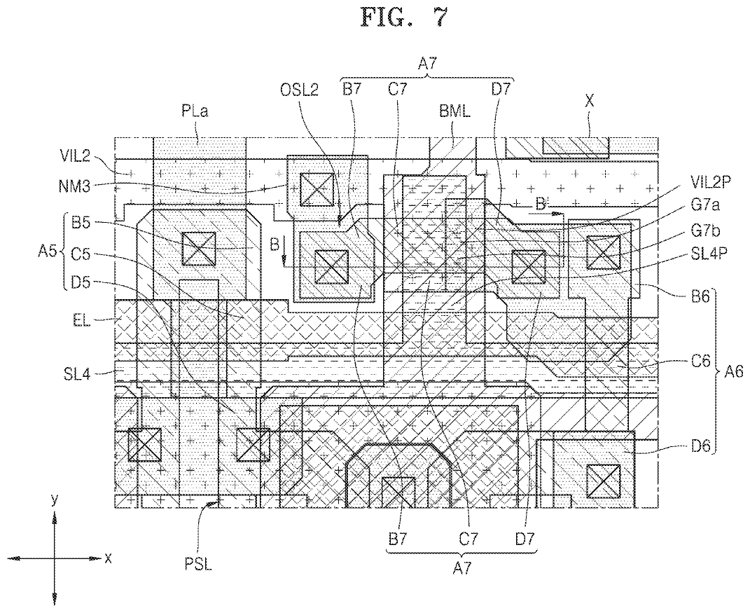

FIG. 7 is an enlarged schematic plan view of a region X of FIG. 5 and is an enlarged schematic view of a portion of the second initialization transistor T7 (see FIG. 5).

Referring to FIGS. 5 and 7, the second initialization transistor T7 may include the seventh semiconductor layer A7. The seventh semiconductor layer A7 may correspond to the second oxide semiconductor pattern layer OSL2. The seventh semiconductor layer A7 may be spaced apart from each other between the fifth semiconductor layer A5 and the sixth semiconductor layer A6 of the silicon semiconductor pattern layer PSL.

The seventh semiconductor layer A7 may be arranged between the main portion of the second initialization voltage line VIL2 and the main portion of the fourth scan line SL4, e.g., in a plan view. As described above, the second initialization voltage line VIL2 may include a main portion and a protrusion VIL2P. The main portion of the second initialization voltage line VIL2 may extend in the x-axis direction, and the protrusion VIL2P may extend from the main portion in the y-axis direction perpendicular to the x-axis direction. The fourth scan line SL4 may include the main portion and the protrusion SLAP. The main portion of the fourth scan line SL4 may extend in the x-axis direction, and the protrusion SL4P may extend from the main portion in the y-axis direction. The main portion of the second initialization voltage line VIL2 may be spaced apart from the main portion of the fourth scan line SL4.

The protrusion VIL2P of the second initialization voltage line VIL2 may be a portion protruding from the main portion of the second initialization voltage line VIL2 to the seventh semiconductor layer A7. The protrusion VIL2P of the second initialization voltage line VIL2 may overlap the seventh channel region C7 of the seventh semiconductor layer A7. The protrusion VIL2P of the second initialization voltage line VIL2 may include a seventh lower gate electrode G7a. The second initialization voltage VAINT (see FIG. 2) may be applied to the seventh lower gate electrode G7a.

The protrusion SL4P of the fourth scan line SL4 may be a portion protruding from the main portion of the fourth scan line SL4 to the seventh semiconductor layer A7. The protrusion SL4P of the fourth scan line SL4 may overlap the seventh channel region C7 of the seventh semiconductor layer A7. The protrusion SLAP of the fourth scan line SL4 may include the seventh upper gate electrode G7b. The protrusion SL4P of the fourth scan line SL4 may overlap the protrusion VIL2P of the second initialization voltage line VIL2. A fourth scan signal EX (see FIG. 2) may be applied to the seventh upper gate electrode G7b.

The second initialization transistor T7 may have a double gate structure including gate electrodes respectively over and below the seventh semiconductor layer A7.

In an embodiment, the fourth scan line SL4 may overlap the emission control line EL.

In an embodiment, the emission control line EL and the fourth scan line SL4 may transfer different signals. In an embodiment, the fourth scan line SL4 and the emission control line EL may receive signals from one of the scan driving circuits 20 (see FIG. 1) on two opposite sides of the display area DA. In an example, the emission control line EL may receive emission control signals EM from the scan driving circuit 20 on the left side of the display apparatus 10, and the fourth scan line SL4 may receive fourth scan signals EX from the scan driving circuit 20 on the right side of the display apparatus 10.

In a comparative example, the second initialization transistor may include an oxide semiconductor layer, and the gate electrode of the second initialization transistor may be provided as a portion of the emission control line that transfers emission control signals EM. The emission control line may include the gate electrode of the second initialization transistor, the gate electrode of the operation control transistor, and the gate electrode of the emission control transistor. For example, because an emission control signal EM for driving of the second initialization transistor is provided through an emission control line, the operation control transistor and the emission control transistor are immediately turned off and the second initialization voltage initializes the sub-pixel electrode of the light-emitting diode, coupling due to the emission control signal EM may not occur to the sub-pixel electrode of the light-emitting diode. Accordingly, in a display apparatus supporting variable frequency driving, influences of brightness deviation according to a bias degree of a driving transistor may become relatively large. Variable refresh rate (VRR) index of a display apparatus may deteriorate. Here, a variable refresh rate (VRR) index represents a rate of change in brightness according to a change in a frequency of a display apparatus.

However, according to an embodiment, the seventh upper gate electrode G7b of the second initialization transistor T7 may be integral with the fourth scan line SL4, which is separated (or spaced apart) from the emission control line EL. For example, because a fourth scan signal EX for driving the second initialization transistor T7 is transferred through the fourth scan line SL4, the second initialization transistor T7 may be driven, and simultaneously, the operation control transistor T5 and the emission control transistor T6 may not be immediately turned off. Accordingly, coupling due to an emission control signal EM may occur to the sub-pixel electrode of the light-emitting diode. In a display apparatus 10 supporting variable frequency driving, influences of brightness deviation according to a bias degree of the driving transistor T1 may be reduced using the coupling phenomenon. Accordingly, a variable refresh rate (VRR) index may improve, and a display apparatus 10 of high resolution with improved display quality may be implemented.

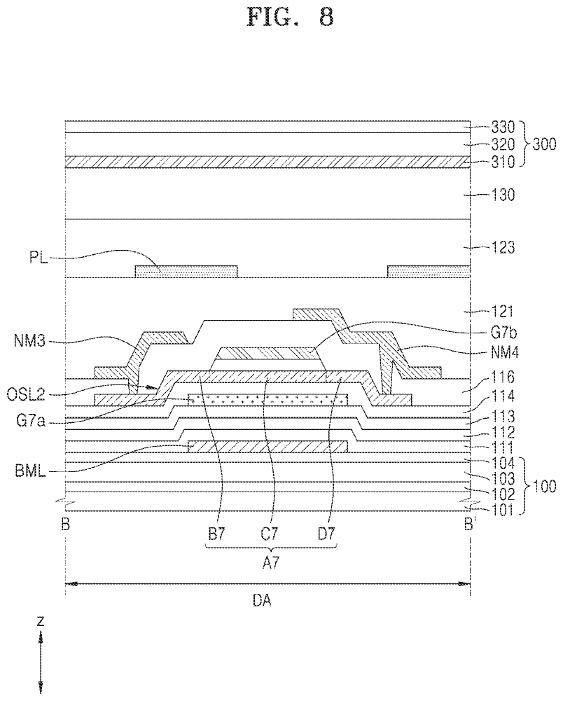

FIG. 8 is a schematic cross-sectional view of the second initialization transistor T7. taken along line B-B′ of FIG. 7.

Referring to FIGS. 7 and 8, the bottom metal layer BML may be disposed on the substrate 100. The substrate 100 may include, for example, the first organic base layer 101, the first inorganic barrier layer 102, the second organic base layer 103, and the second inorganic barrier layer 104. The buffer layer 111, the first gate insulating layer 112, and the first interlayer insulating layer 113 may be sequentially disposed on the bottom metal layer BML.

The seventh lower gate electrode G7a may be disposed on the first interlayer insulating layer 113. The seventh lower gate electrode G7a and the second initialization voltage line VIL2 may be integral with each other (see FIG. 7). The second initialization voltage VAINT (see FIG. 2) may be applied to the seventh lower gate electrode G7a. The second interlayer insulating layer 114 may be disposed on the seventh lower gate electrode G7a. For example, the second initialization transistor T7 may have a structure, which is similar to the structure of the compensation transistor T3 in FIG. 4. Referring to FIGS. 4 and 8, the first capacitor electrode (e.g., lower electrode) CE1 of the first capacitor Cst and the first gate electrode G1 of the driving transistor T1 may be disposed on the same layer (e.g., the first gate insulating layer 112). The second capacitor electrode (e.g., upper electrode) CE2 of the first capacitor Cst and the seventh lower gate electrode G7a of the second initialization transistor T7 may be disposed on the same layer (e.g., the first interlayer insulating layer 113.

The seventh semiconductor layer A7 may be disposed on the second interlayer insulating layer 114. The seventh semiconductor layer A7 may include an oxide semiconductor material. The seventh semiconductor layer A7 may be the second oxide semiconductor pattern layer OSL2. The seventh semiconductor layer A7 may include the seventh channel region C7, a first region B7, and a second region D7. The first region B7 and the second region D7 may be disposed on two opposite sides of the seventh channel region C7. Referring to FIGS. 4 and 8, a vertical distance between the substrate 100 and the seventh semiconductor layer A7 of the second initialization transistor T7 may be greater than a vertical distance between the substrate 100 and the first semiconductor layer A1 of the driving transistor (e.g., first thin-film transistor) T1.

The seventh upper gate electrode G7b may be disposed over the seventh semiconductor layer A7. The second gate insulating layer 115 may be disposed between the seventh upper gate electrode G7b and the seventh semiconductor layer A7. Although it is shown in FIG. 8 that the second gate insulating layer 115 is disposed only between the seventh upper gate electrode G7b and the seventh lower gate electrode G7a, embodiments are not limited thereto. In another embodiment, the second gate insulating layer 115 may be disposed to cover (e.g., entirely cover) the substrate 100. The seventh upper gate electrode G7b and the seventh lower gate electrode G7a may overlap the seventh channel region C7 over and below the seventh semiconductor layer A7.

The third interlayer insulating layer 116 may be disposed on the seventh upper gate electrode G7b. The third connection electrode NM3 and the fourth connection electrode NM4 may be disposed on the third interlayer insulating layer 116. The third connection electrode NM3 may be connected (e.g., electrically connected) to the first region B7 of the seventh semiconductor layer A7 through a contact hole defined in the third interlayer insulating layer 116. Because the third connection electrode NM3 is connected to the second initialization voltage line VIL2, the second initialization voltage line VIL2 may be electrically connected to the first region B7 of the seventh semiconductor layer A7 through the third connection electrode NM3. The fourth connection electrode NM4 may be connected (e.g., electrically connected) to the second region D7 of the seventh semiconductor layer A7 through a contact hole defined in the third interlayer insulating layer 116. As described above, because the fourth connection electrode NM4 is connected (e.g., electrically connected) to the sixth connection electrode NM6 (see FIG. 6H), and the sixth connection electrode NM6 is connected (e.g., electrically connected) to the sub-pixel electrode of the light-emitting diode, the second region D7 of the seventh semiconductor layer A7 may be electrically connected to the sub-pixel electrode of the light-emitting diode through the fourth connection electrode NM4.

The first organic insulating layer 121 may be disposed on the third connection electrode NM3 and the fourth connection electrode NM4. The driving voltage line PL may be disposed on the first organic insulating layer 121. The second organic insulating layer 123 may be disposed on the driving voltage line PL. The bank layer 130 may be disposed on the second organic insulating layer 123.

The encapsulation layer 300 may be disposed on the bank layer 130. In an embodiment, the encapsulation layer 300 may include the first inorganic encapsulation layer 310, the second inorganic encapsulation layer 330, and the organic encapsulation layer 320. The second inorganic encapsulation layer 330 may be over the first inorganic encapsulation layer 310, and the organic encapsulation layer 320 may be between the first inorganic encapsulation layer 310 and the second inorganic encapsulation layer 330.

According to an embodiment, a display apparatus 10 of high resolution with high display quality and improved power consumption may be provided. However, the scope of the disclosure is not limited by this effect.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display apparatus comprising:
a substrate;
a scan line disposed over the substrate and extending in a first direction;
an initialization voltage line disposed over the substrate and extending in the first direction;
a first thin-film transistor including a first semiconductor layer and a first gate electrode insulated from the first semiconductor layer, the first semiconductor layer including a silicon semiconductor; and
a second thin-film transistor including a second semiconductor layer and a second gate electrode insulated from the second semiconductor layer, the second semiconductor layer including an oxide semiconductor, wherein
the second semiconductor layer is disposed between the scan line and the initialization voltage line in a plan view, and
the second gate electrode extends from the scan line in a second direction perpendicular to the first direction.

2. The display apparatus of claim 1, wherein the second semiconductor layer is electrically connected to the initialization voltage line.

3. The display apparatus of claim 1, wherein a vertical distance from the substrate to the second semiconductor layer is greater than a vertical distance from the substrate to the first semiconductor layer.

4. The display apparatus of claim 1, wherein
the second thin-film transistor further includes a third gate electrode disposed below the second semiconductor layer to overlap the second semiconductor layer, and
the third gate electrode extends from the initialization voltage line in the second direction.

5. The display apparatus of claim 4, further comprising:
a first capacitor including a lower electrode and an upper electrode over the lower electrode, wherein
the lower electrode and the first gate electrode are disposed on a same layer, and
the upper electrode and the third gate electrode are disposed on a same layer.

6. The display apparatus of claim 1, further comprising:
an emission control line spaced apart from the initialization voltage line and extending in the first direction,
wherein the emission control line overlaps the scan line.

7. The display apparatus of claim 6, wherein the emission control line and the first gate electrode are disposed on a same layer.

8. The display apparatus of claim 1, further comprising:
a third thin-film transistor including a third semiconductor layer and a fourth gate electrode insulated from the third semiconductor layer, wherein
the third semiconductor layer includes an oxide semiconductor, and
the third semiconductor layer is spaced apart from the second semiconductor layer of the second thin-film transistor.

9. The display apparatus of claim 8, further comprising:
a second capacitor including a lower electrode and an upper electrode, wherein
the lower electrode and the first gate electrode are disposed on a same layer, and
the upper electrode and the third semiconductor layer are disposed on a same layer.

10. The display apparatus of claim 9, wherein the upper electrode of the second capacitor extends from the third semiconductor layer.

11. A display apparatus comprising:
a substrate;
a scan line disposed over the substrate and extending in a first direction;
an initialization voltage line disposed over the substrate and extending in the first direction;
a first thin-film transistor disposed over the substrate and including a first semiconductor layer and a first gate electrode insulated from the first semiconductor layer, the first semiconductor layer including a silicon semiconductor; and
a second thin-film transistor including a second semiconductor layer, a second gate electrode, and a third gate electrode, the second semiconductor layer including an oxide semiconductor, the second gate electrode disposed over the second semiconductor layer, the third gate electrode overlapping the second gate electrode and disposed below the second semiconductor layer,
wherein the third gate electrode extends from the initialization voltage line in a second direction perpendicular to the first direction.

12. The display apparatus of claim 11, wherein the second semiconductor layer is disposed between the scan line and the initialization voltage line in a plan view.

13. The display apparatus of claim 11, wherein the second semiconductor layer is electrically connected to the initialization voltage line.

14. The display apparatus of claim 11, wherein the second gate electrode extends from the scan line in the second direction.

15. The display apparatus of claim 11, further comprising:
a first capacitor including a lower electrode and an upper electrode over the lower electrode, wherein
the lower electrode and the first gate electrode are disposed on a same layer, and
the upper electrode and the third gate electrode are disposed on a same layer.

16. The display apparatus of claim 11, further comprising:
an emission control line spaced apart from the initialization voltage line and extending in the first direction,
wherein the emission control line overlaps the scan line.

17. The display apparatus of claim 16, wherein the emission control line and the first gate electrode is disposed on a same layer.

18. The display apparatus of claim 11, further comprising:
a third thin-film transistor including a third semiconductor layer and a fourth gate electrode insulated from the third semiconductor layer, wherein
the third semiconductor layer includes an oxide semiconductor, and
the third semiconductor layer is spaced apart from the second semiconductor layer of the second thin-film transistor.

19. The display apparatus of claim 18, further comprising:
a second capacitor including a lower electrode and an upper electrode, wherein
the lower electrode and the first gate electrode are disposed on a same layer, and
the upper electrode and the third semiconductor layer are disposed on a same layer.

20. The display apparatus of claim 19, wherein the upper electrode of the second capacitor extends from the third semiconductor layer.
